(19) United States
(12) Patent Application Publication
(10) Pub. No.: US 2008/0007900 A1
(43) Pub. Date: Jan. 10, 2008

(54) ELECTRONIC DEVICE WITH AN ACCESSORY

(75) Inventor: Wei Chieh Chen, Taoyuan County (TW)

Correspondence Address: QUINTERO LAW OFFICE, PC, 2210 MAIN STREET, SUITE 200, SANTA MONICA, CA, 90405, US

(73) Assignee: BENQ CORPORATION, TAOYUAN (TW)

(21) Appl. No.: 11/767,387

(22) Filed: Jun. 22, 2007

(30) Foreign Application Priority Data
Jul. 5, 2006 (TW) TW95124453

(51) Int. Cl. H05K 7/00

(52) U.S. Cl. 361/679

(57) ABSTRACT

An electronic device with an accessory is disclosed. The electronic device with an accessory comprises two shells and a connecting element. A slot having a plurality of teeth is located between the shells. The connecting element comprises a protrusion and a damper. The protrusion connects to the accessory. The damper is installed in the slot for avoiding the connecting element moving.

### BACKGROUND OF THE INVENTION

1. Field of the Invention

The invention relates to an electronic device, and more particularly relates to an electronic device with an accessory.

2. Description of the Related Art

Referring to FIG. 1, a conventional electronic device, a display 10, comprises a front shell 11 and a back shell 12. The front shell 11 is tightly connected to the back shell 12 to protect the display 10.

Webcams 13 are currently experiencing huge popularity. A webcam 13 is used for videoconferencing or other video communication. A webcam 13 is typically adhered to or hung on the display 10. If a webcam 13 is placed on, but not fixed to the display, the webcam 13 may easily fall from the display 10 and be damaged. Although fixing the webcam 13 to the display 10 via hanging or adhesive ensures stability, changing the position of the webcam 13 is inconvenient. Thus, when changing position, the webcam 13 must be re-hung or re-adhered.

### BRIEF SUMMARY OF INVENTION

The invention provides an electronic device. An accessory is assembled on the electronic device. The electronic device comprises two shells and a connecting element. A slot having a plurality of teeth is located between the shells. The connecting element comprises a protrusion and a damper. The protrusion connects to the accessory. The damper is installed in the slot to prevent movement of the connecting element.

The connecting element further comprises an elastic element and a tubular portion. The elastic element is located in the tubular portion and connected to the protrusion.

The slot comprises a plurality of holes for accommodating the tubular portion.

The protrusion comprises a screw portion for fixing the accessory.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic view showing a conventional electronic device with an accessory;

FIG. 2 is a schematic view showing the electronic device of the invention connecting to the accessory;

FIG. 3 is an exploded view of the shells and the connecting element of the electronic device of the invention;

FIG. 4 is a schematic view showing the connecting element;

FIGS. 5A to 5C show that the connecting element moves on the electronic device;

FIG. 6 is a schematic view showing the electronic device connected to a microphone;

FIG. 7 is a schematic view to show the electronic device to connect to a paper clip;

FIG. 8 is a schematic view to show another embodiment of the electronic device of the invention;

FIG. 9 is a schematic view to show another embodiment of the connecting element of the invention;

FIG. 10 is a lateral view of FIG. 9.

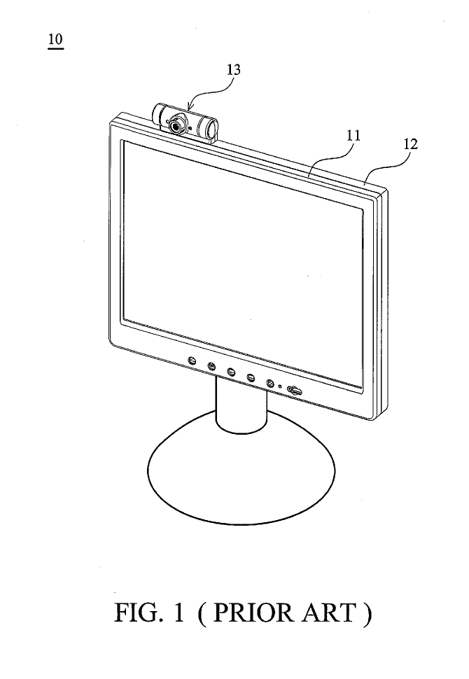

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

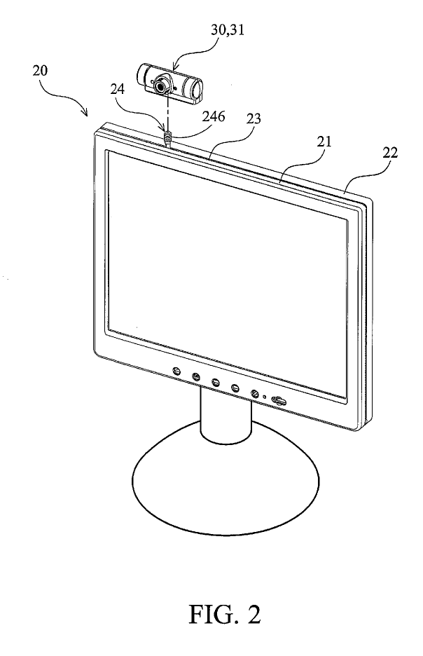

Referring to FIG. 2, an electronic device of the invention may be a display 20, a personal digital assistant (PDA) or a portable computer. This embodiment provides a display 20 as an example of an electronic device. Note that an accessory 30 is movably connected to the display 20. The display 20 comprises two shells 21 and 22 and a connecting element 24. A slot 23 is located between two shells 21 and 22. The connecting element 24 is movably installed in the slot 23. This embodiment provides a webcam 31 as an example of an accessory 30. The connecting element 24 comprises a screw portion 246 for fixing the webcam 31 and the display 20. Note that the connecting element 24 can be moved to change the position, thus, the webcam 31 can be adjusted.

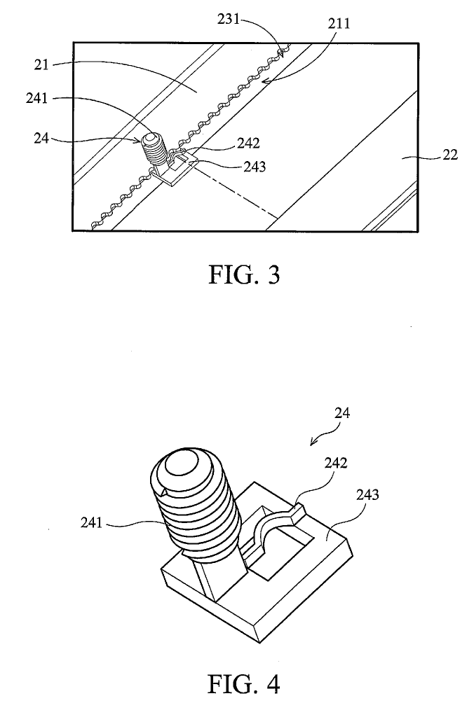

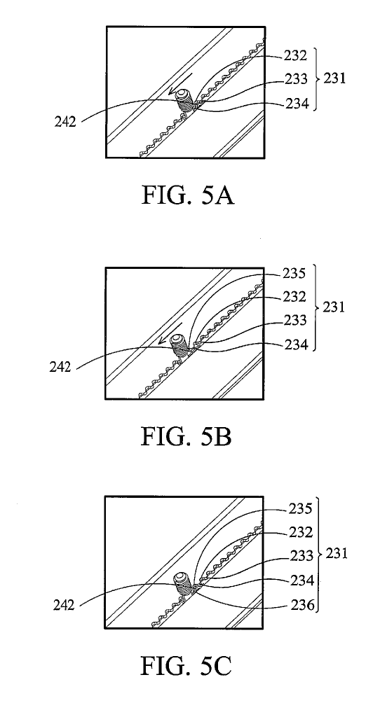

Referring to FIGS. 2 to 4, the connecting element 24 comprises a protrusion 241, a damper 242 and a sliding portion 243. The shells 21 and 22 are a front shell 21 and a back shell 22. The front shell 21 and the back shell 22 form a space 211 for accommodating the sliding portion 243. The slot 23 comprises a plurality of teeth 231. The damper 242 comprises a flexible material and is installed on the same surface as teeth 231. Referring to FIGS. 4 and 5A to 5C, the teeth 231 comprises a plurality of depressions 232 and 235 and a plurality of tips 233, 234 and 236. FIG. 5A shows that the damper 242 in the depression 232 keeps a curved shape. The tips 233 and 234 are respectively disposed adjacent to two sides of the depression 232, thus, the damper 242 is positioned and fixed between the tips 233 and 234. When changing the position, as shown in FIG. 5B, the webcam 31 is forced to move from depression 232 to depression 235 along the direction of the arrow shown in FIG. 5B. When the damper 242 passes through the tip 234, the tip 234 presses the damper 242 flat. The shape of the damper 242 changes to pass through the tip 234 and then reaches the depression 235. When force is not exerted on webcam 31 the damper 242 is positioned and fixed between the tips 234 and 236 (shown in FIG. 5C).

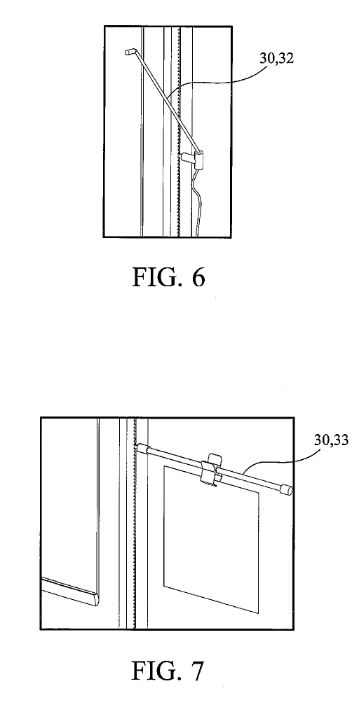

Referring to FIGS. 6 and 7, the accessory 30 of the electronic device of the invention may be a webcam 31, a microphone 32, or a paper clip 33, as shown in FIG. 7, for holding papers. Thus, the electronic device provides kinds of accessory 30 to be fixed thereon but also allows accessory 30 to be movably adjusted.

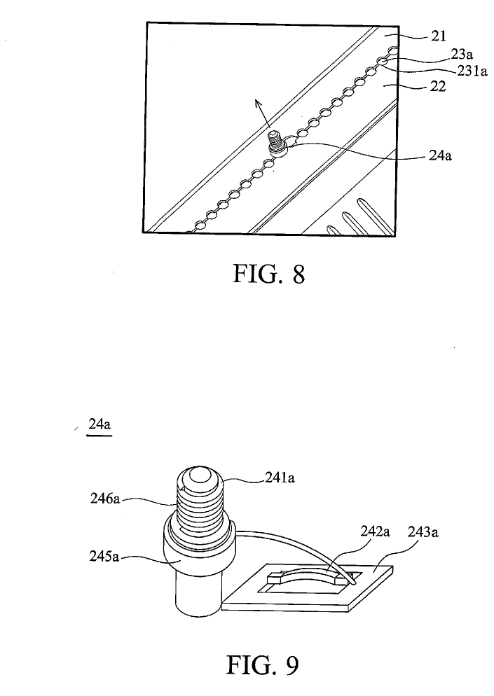

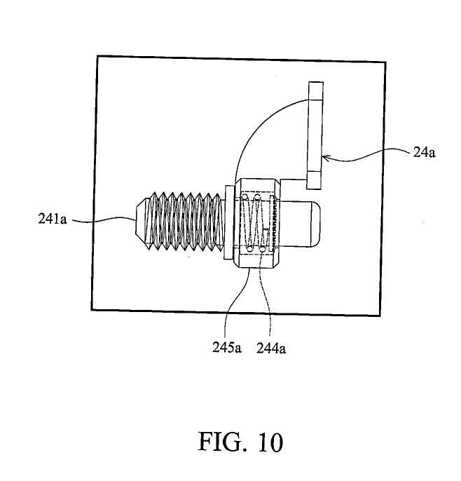

FIGS. 8 to 10 show another embodiment of the electronic device. The display comprises two shells 21 and 22 and a connecting element 24a. A slot 23a is located between the shells 21 and 22. Note that the slot 23a comprises a plurality of holes 231a. The connecting element 24a is installed movably in the slot 23a and is connected to the accessory 30 (shown in FIG. 2). The connecting element 24a comprises a protrusion 241a, a damper 242a, a sliding portion 243a, an elastic element 244a and a tubular portion 245a. The elastic element 244a is installed in the tubular portion 245a and connected to the protrusion 241a. In this embodiment, the connecting element 24a does not directly move in the slot 23a. When the connecting element 24a is fixed in the slot 23a, the tubular portion 245a is inserted into the hole 231a. When the position of the webcam 31 is changed, as shown in FIG. 2, the protrusion 241a is pulled upward along the direction indicated by the arrow in FIG. 8, until the tubular portion 245a separates from the slot 23a. The connecting element 24a is forced to move along the slot 23a. The movement of the connecting element 24a is approximately similar, thus, further description is omitted.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device, connected to an accessory, comprising:
two shells, connected to each other, comprising:
a slot, comprising a plurality of teeth located between the shells; and
a connecting element movably disposed between the shells, comprising:
a protrusion for connecting the accessory; and
a damper located in the slot and positioned via the teeth.

2. The electronic device as claimed in claim 1, wherein the connecting element further comprises an elastic element and a tubular portion, the elastic element is located in the tubular portion and connected to the protrusion.

3. The electronic device as claimed in claim 2, wherein the slot comprises a plurality of holes for containing the tubular portion.

4. The electronic device as claimed in claim 1, wherein the protrusion comprises a screw portion for fixing the accessory.

5. The electronic device as claimed in claim 1, wherein the connecting element further comprises a sliding portion and the shells form a space, the sliding portion slides in the space.

6. An electronic device, comprising:
two shells, connected to each other, comprising:
a slot, comprising a plurality of teeth located between the shells;
a connecting element movably disposed between the shells, comprising:
a protrusion for connecting the accessory; and
a damper located in the slot and positioned via the teeth; and
an accessory, connected to the protrusion.

7. The electronic device as claimed in claim 6, wherein the connecting element further comprises an elastic element and a tubular portion, the elastic element is located in the tubular portion and connected to the protrusion.

8. The electronic device as claimed in claim 7, wherein the slot comprises a plurality of holes for containing the tubular portion.

9. The electronic device as claimed in claim 7, wherein the protrusion comprises a screw portion for fixing the accessory.

10. The electronic device as claimed in claim 6, wherein the connecting element further comprises a sliding portion and the shells form a space, the sliding portion slides in the space.

11. The electronic device as claimed in claim 6, wherein the accessory comprises a webcam.

12. The electronic device as claimed in claim 6, wherein the accessory comprises a paper clip.

13. The electronic device as claimed in claim 6, wherein the accessory comprises a microphone.
